(19) United States
(12) Patent Application Publication
(10) Pub. No.: US 2026/0250847 A1
(43) Pub. Date: Aug. 27, 2026

(54) SUBSTRATE PROCESSING APPARATUS, GAS SUPPLY SUPPRESSION STRUCTURE, METHOD OF PROCESSING SUBSTRATE, METHOD OF MANUFACTURING SEMICONDUCTOR DEVICE, AND RECORDING MEDIUM

(71) Applicant: Kokusai Electric Corporation, Tokyo (JP)

(72) Inventors: Tadashi TAKASAKI, Toyama-shi (JP); Naofumi OHASHI, Toyama-shi (JP)

(73) Assignee: Kokusai Electric Corporation, Tokyo (JP)

(21) Appl. No.: 19/648,547

(22) Filed: Apr. 15, 2026

Related U.S. Application Data
(63) Continuation of application No. PCT/JP2024/012436, filed on Mar. 27, 2024.

(51) Int. Cl. C23C 16/455; C23C 16/458; C23C 16/52; H01J 37/32

(52) U.S. Cl. CPC C23C 16/45589; C23C 16/4586; C23C 16/52; H01J 37/3244

(57) ABSTRACT

There is provided a technique that includes: a process chamber in which a substrate is processed; a substrate support provided in the process chamber and capable of supporting a first substrate or a second substrate having an outer diameter smaller than that of the first substrate; a gas supplier including an annular first region provided at a position facing the substrate support and having an inner diameter larger than the outer diameter of the second substrate, and a second region provided on an inner peripheral side of the first region, and capable of supplying gas into the process chamber from the first region and the second region; and a suppressor configured to suppress supply of gas from the first region into the process chamber when the second substrate is processed.

### CROSS-REFERENCE TO RELATED APPLICATION

This application is a Bypass Continuation Application of PCT International Application No. PCT/JP2024/012436, filed on March 27, 2024, the entire contents of which are incorporated herein by reference.

### BACKGROUND

### FIELD

The present disclosure relates to a substrate processing apparatus, a gas supply suppression structure, a method of processing a substrate, a method of manufacturing a semiconductor device, and a recording medium.

### DESCRIPTION OF THE RELATED ART

As one step of a semiconductor device manufacturing process, a technique of supplying a process gas to a substrate to form a film on the substrate is known.

### SUMMARY

The present disclosure provides a technique capable of stably treating a substrate regardless of the size of the substrate.

According to an aspect of the present disclosure,

there is provided a technique that includes:

a process chamber in which a substrate is processed;

a substrate support provided in the process chamber and capable of supporting a first substrate or a second substrate having an outer diameter smaller than that of the first substrate;

a gas supplier including an annular first region provided at a position facing the substrate support and having an inner diameter larger than the outer diameter of the second substrate, and a second region provided on an inner peripheral side of the first region, and capable of supplying gas into the process chamber from the first region and the second region; and

a suppressor configured to suppress supply of gas from the first region into the process chamber when the second substrate is processed.

### BRIEF DESCRIPTION OF THE DRAWINGS

FIG. 1 is a schematic configuration diagram of a substrate processing apparatus according to an embodiment of the present disclosure, illustrating a state where a first substrate is set.

FIG. 2 is a schematic configuration diagram of the substrate processing apparatus according to the embodiment of the present disclosure, illustrating a state where a second substrate is set.

FIG. 3 is a diagram illustrating a gas supply system of the substrate processing apparatus according to the embodiment of the present disclosure.

FIG. 4 is a plan view of the substrate processing apparatus of FIG. 1 as viewed from a direction of an arrow 4X.

FIG. 5 is a plan view of the substrate processing apparatus of FIG. 2 as viewed from a direction of an arrow 5X.

FIG. 6 is a block diagram illustrating a control system used in the substrate processing apparatus according to the embodiment of the present disclosure.

FIG. 7 is a schematic configuration diagram of a substrate processing apparatus according to another embodiment of the present disclosure, illustrating a state where a first substrate is set.

FIG. 8 is a schematic configuration diagram of the substrate processing apparatus according to the other embodiment of the present disclosure, illustrating a state where a second substrate is set.

FIG. 9 is a schematic configuration diagram of a storage of a suppressor used in the substrate processing apparatus according to the other embodiment of the present disclosure.

### DETAILED DESCRIPTION

### Aspect of present disclosure

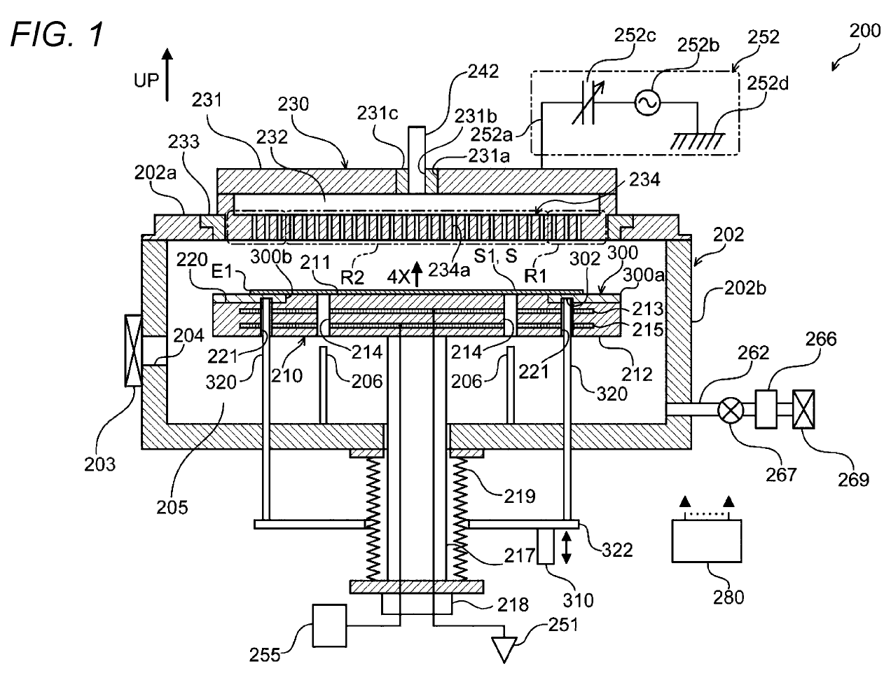

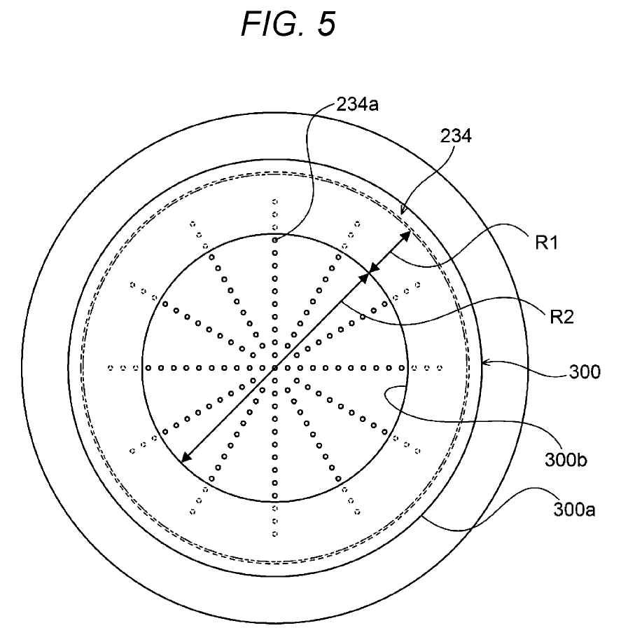

An aspect of the present disclosure will be described below mainly with reference to FIGS. 1 to 6. Note that the drawings used in the following description are all schematic, and a dimensional relationship between elements, a ratio between the elements, and the like in the drawings do not necessarily coincide with actual ones. In addition, a dimensional relationship between elements, a ratio between the elements, and the like do not necessarily coincide among a plurality of drawings.

### (1) Configuration of substrate processing apparatus

As illustrated in FIG. 1, a substrate processing apparatus 200 is an apparatus capable of processing a substrate S. In the drawing, an upper side of the substrate processing apparatus 200 is indicated by an arrow UP. The substrate processing apparatus 200 includes a process container 202. The process container 202 is, for example, a hermetically sealed flat container having a circular cross section. The process container 202 is made of, for example, a metal material such as aluminum (Al) or stainless steel (SUS).

### Process chamber

In the process container 202, a process chamber 205 in which the substrate S such as a silicon wafer is processed is formed.

The process container 202 includes an upper process container 202a and a lower process container 202b.

A substrate loading/unloading port 204 adjacent to a gate valve 203 is formed on a side surface of the lower process container 202b. The substrate S is moved between the lower process container 202b and a transfer chamber (not illustrated) via the substrate loading/unloading port 204 by a transfer mechanism (not illustrated).

A plurality of lift pins 206 are provided on a bottom of the lower process container 202b. These lift pins 206 extend upward.

### Substrate support

In the process chamber 205, a substrate support 210 that supports the substrate S is disposed. The substrate support 210 is configured to be able to support a first substrate S1 or a second substrate S2 having an outer diameter smaller than that of the first substrate S1 among the substrates S. In the present embodiment, as an example, the first substrate S1 is a substrate having a diameter of 300 mm, and the second substrate S2 is a substrate having a diameter of 200 mm.

The substrate support 210 mainly includes a substrate mounting surface 211 on which the substrate S is mounted, a substrate mounting table 212 having the substrate mounting surface 211 on a surface thereof, a heater 213 serving as a heating source provided in the substrate mounting table 212, and a bias electrode 215 serving as an electrode provided in the substrate mounting table 212.

The substrate mounting surface 211 is a surface having a diameter larger than that of the first substrate S1. One first substrate S1 or one second substrate S2 can be mounted on the substrate mounting surface 211.

The substrate mounting table 212 has through-holes 214 through which the lift pins 206 pass at positions corresponding to the lift pins 206, respectively.

The heater 213 is connected to a heater controller 255 via electric wiring. The heater controller 255 heats the heater 213 to a desired temperature in response to an instruction from a controller 280.

The bias electrode 215 is disposed below the heater 213. The bias electrode 215 is connected to a ground 251 via electric wiring.

The substrate mounting table 212 is supported by a shaft 217. The shaft 217 penetrates a bottom of the process container 202. The shaft 217 is connected to an elevator 218 outside the process container 202. The shaft 217 is insulated from the process container 202.

When the elevator 218 is operated, the shaft 217 and the substrate mounting table 212 are moved up and down. That is, the substrate S mounted on the substrate mounting surface 211 can be moved up and down by the operation of the elevator 218.

A circumference of a lower end of the shaft 217 is covered with a bellows 219. The inside of the process chamber 205 is airtightly held by the bellows 219.

When the substrate S is transferred, the substrate mounting table 212 is lowered to a position where the substrate mounting surface 211 faces the substrate loading/unloading port 204. When the substrate S is processed, the substrate mounting table 212 rises to the processing position illustrated in FIG. 1.

In addition, a counterbore 220 capable of housing a suppressor 300 described later is provided in the substrate support 210. The shape of the counterbore 220 is a shape corresponding to the suppressor 300. For example, the counterbore 220 is formed in a circumferential shape so as to be able to support the suppressor 300 on a bottom surface thereof. Therefore, the suppressor 300 can be housed in the counterbore 220.

An exhaust pipe 262 is connected to the process container 202 so as to communicate with the process chamber 205. Specifically, the exhaust pipe 262 is connected to the lower process container 202b.

The exhaust pipe 262 includes an auto pressure controller (APC) 266 that is a pressure regulator that regulates the inside of the process chamber 205 to a predetermined pressure. The APC 266 has a valve body (not illustrated) whose opening degree can be regulated, and regulates conductance of the exhaust pipe 262 according to an instruction from the controller 280. The exhaust pipe 262 includes a valve 267 on an upstream side of the APC 266. The exhaust pipe 262 includes a dry pump 269 on a downstream side of the APC 266. The dry pump 269 discharges an atmosphere in the process chamber 205 via the exhaust pipe 262. The exhaust pipe 262, the valve 267, and the APC 266 mainly constitute an exhaust system. The dry pump 269 may be included in the exhaust system.

### Gas supplier

As illustrated in FIG. 1, the upper process container 202a has a shower head 230 serving as a gas supplier.

A lid 231 of the shower head 230 has a through-hole 231a. An insulator 231c is provided on an inner periphery of the through-hole 231a. The insulator 231c has a gas introduction hole 231b. The gas introduction hole 231b communicates with a common gas supply pipe 242 described later. The insulator 231c electrically insulates the common gas supply pipe 242 from the lid 231.

A power supply line 252a is connected to the lid 231. The power supply line 252a includes a high-frequency power source 252b and a matcher 252c in this order from an upstream side. The high-frequency power source 252b is connected to a ground 252d. The power supply line 252a and the matcher 252c mainly constitute a power supply system 252. The high-frequency power source 252b may be included in the power supply system 252.

The shower head 230 includes a dispersion plate 234 serving as a dispersion mechanism for dispersing gas. An upstream side of the dispersion plate 234 is a buffer space 232, and a downstream side thereof is the process chamber 205.

The dispersion plate 234 is disposed so as to face the substrate support 210. Specifically, the dispersion plate 234 is disposed so as to face the substrate mounting surface 211 in the vertical direction. The dispersion plate 234 is formed in, for example, a disk shape.

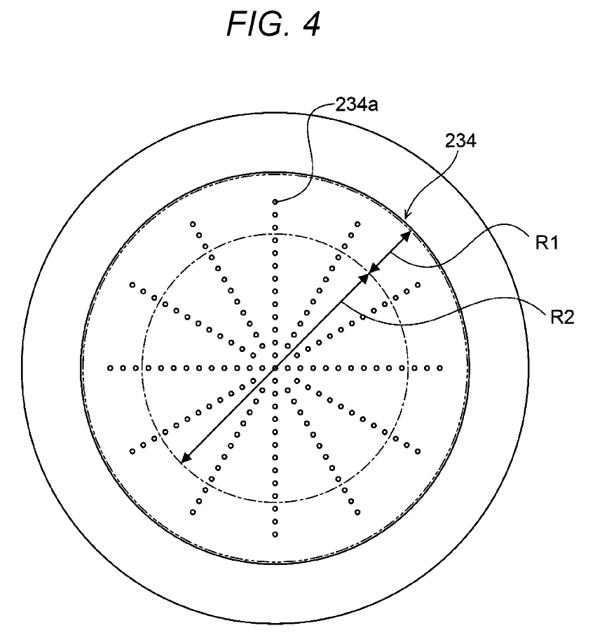

The dispersion plate 234 has a plurality of through-holes 234a serving as passing portions through which gas can pass. As illustrated in FIGS. 1 and 4, the plurality of through-holes 234a is formed over the entire surface of the dispersion plate 234.

The dispersion plate 234 has an annular first region R1 having an inner diameter larger than an outer diameter of the second substrate S2 and a second region R2 provided on an inner peripheral side of the first region. Gas is supplied into the process chamber 205 from the plurality of through-holes 234a included in the first region R1 of the dispersion plate 234 and the plurality of through-holes 234a included in the second region R2 of the dispersion plate 234.

The first region R1 of the dispersion plate 234 is a region facing a surface of the first substrate S1 in a state where the first substrate S1 is supported by the substrate support 210, and not facing a surface of the second substrate S2 in a state where the second substrate S2 is supported by the substrate support 210. In addition, the first region R1 is a region facing an edge E1 of the first substrate S1 in a state where the first substrate S1 is supported by the substrate support 210, and not facing the second substrate S2 in a state where the second substrate S2 is supported by the substrate support 210. Note that the first region R1 is a region formed by an edge side portion of the dispersion plate 234.

The second region R2 of the dispersion plate 234 is a region facing a surface of the first substrate S1 in a state where the first substrate S1 is supported by the substrate support 210, and facing a surface of the second substrate S2 in a state where the second substrate S2 is supported by the substrate support 210. In addition, the second region R2 is a region facing a central portion (central portion in a radial direction) of the first substrate S1 in a state where the first substrate S1 is supported by the substrate support 210, and facing the second substrate S2 in a state where the second substrate S2 is supported by the substrate support 210. Note that, in other words, the second region R2 of the dispersion plate 234 is a region constituted by a portion on an inner peripheral side of the edge side of the dispersion plate 234.

The upper process container 202a has a flange, and an insulating support block 233 is mounted and fixed on the flange.

The support block 233 has a flange, and the dispersion plate 234 is mounted and fixed on the flange. The lid 231 is fixed to an upper surface of the support block 233. The support block 233 insulates the lid 231 from the upper process container 202a.

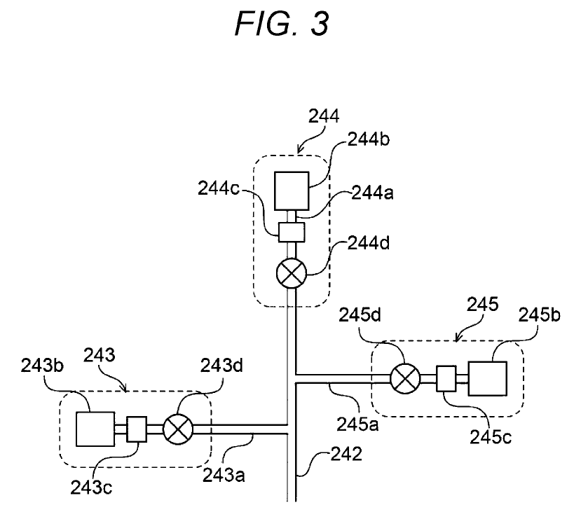

A common gas supply pipe 242 is connected to the lid 231 so as to communicate with the gas introduction hole 231b. As illustrated in FIG. 3, a first gas supply pipe 243a, a second gas supply pipe 244a, and a third gas supply pipe 245a are connected to the common gas supply pipe 242.

The first gas supply pipe 243a includes a first gas source 243b, a mass flow controller (MFC) 243c serving as a flow rate controller, and a valve 243d serving as an on-off valve in this order from an upstream side. Note that the first gas source 243b is a first gas source containing a first element. The first gas is one of the process gases.

The first gas supply pipe 243a, the MFC 243c, and the valve 243d mainly constitute a first gas supply system 243. Note that the first gas source 243b may be included in the first gas supply system 243.

The second gas supply pipe 244a includes a second gas source 244b, an MFC 244c, and a valve 244d serving as an on-off valve in this order from an upstream side. Note that the second gas source 244b is a second gas source containing a second element. The second gas is one of the process gases. The second element gas may be considered as a reactant gas.

The second gas supply pipe 244a, the MFC 244c, and the valve 244d mainly constitute a second gas supply system 244. Note that the second gas source 244b may be included in the second gas supply system 244.

The third gas supply pipe 245a includes a third gas source 245b, an MFC 245c, and a valve 245d serving as an on-off valve in this order from an upstream side. Note that the third gas source 245b is an inert gas source. The inert gas acts as a purge gas for purging gas remaining in the process container 202 and the shower head 230 in a substrate processing step.

The third gas supply pipe 245a, the MFC 245c, and the valve 245d mainly constitute a third gas supply system 245. Note that the third gas source 245b may be included in the third gas supply system 245.

In the present embodiment, any one of the first gas supply system 243, the second gas supply system 244, and the third gas supply system 245, or a combination thereof is collectively referred to as a gas supply system. Note that here, the configuration in which the common gas supply pipe 242 is connected to the gas supply system has been described, but the present disclosure is not limited thereto, and each gas supply system may be configured to supply gas into the process chamber 205 individually.

### Suppressor

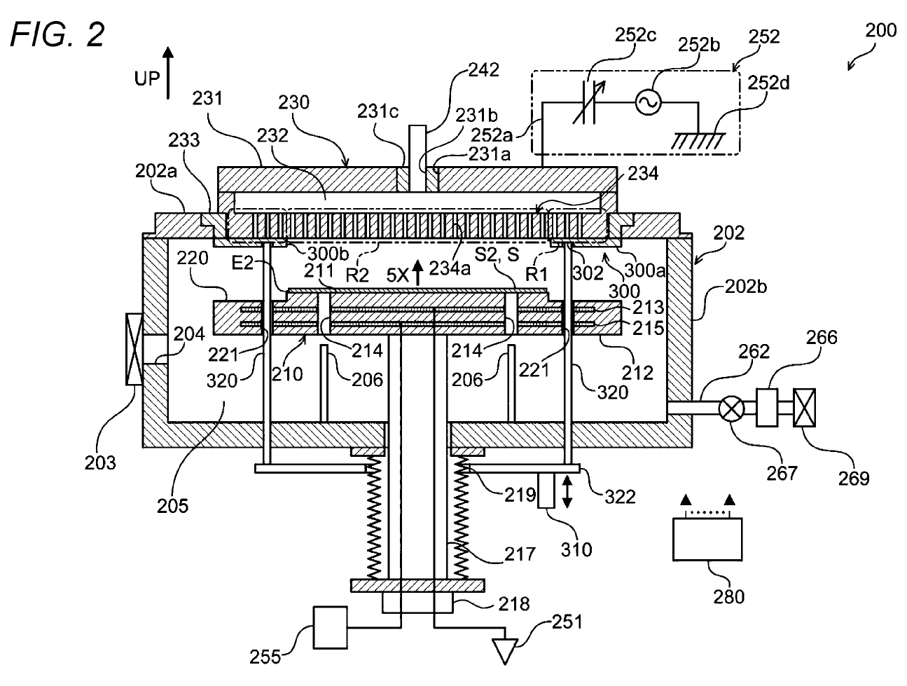

As illustrated in FIGS. 1 and 2, a suppressor 300 is disposed in the process chamber 205. The suppressor 300 is configured to suppress supply (inflow) of gas from the first region R1 into the process chamber 205 when the second substrate S2 is processed. Specifically, the suppressor 300 is provided at a position facing the substrate support 210. The suppressor 300 includes a first portion 300a that suppresses supply of gas from the first region R1 into the process chamber 205, and a second portion 300b serving as a hole through which gas can pass. Here, as illustrated in FIGS. 1 and 2, the diameter of the second portion 300b is larger than the outer diameter of the second substrate S2 and smaller than the outer diameter of the first substrate S1. The shape of the second portion 300b is the same as the outer shape of the second substrate S2. In the present embodiment, as an example, the shape of the first portion 300a is circular, and the shape of the second portion 300b is also circular. That is, the suppressor 300 is paraphrased as a disk-shaped member having a through hole at a center thereof.

As illustrated in FIG. 2, in a state where the second substrate S2 is supported by the substrate support 210, the first portion 300a of the suppressor 300 is disposed above a surface that does not support the second substrate S2 in the substrate support 210. Specifically, the first portion 300a of the suppressor 300 is disposed above the counterbore 220.

The suppressor 300 is disposed between the bias electrode 215 and the shower head 230 when the second substrate S2 is processed. Specifically, the suppressor 300 is disposed between a portion facing the first region R1 in the bias electrode 215 and a portion of the first region R1 of the dispersion plate 234.

The first portion 300a of the suppressor 300 is disposed at least below the first region R1 when the second substrate S2 is processed.

The suppressor 300 is housed in the counterbore 220 when the first substrate S1 is processed. Specifically, in a state where the suppressor 300 is housed in the counterbore 220, a surface of the suppressor 300 forms a part of the substrate mounting surface 211. More specifically, the surface of the suppressor 300 forms an outer peripheral side portion of the substrate mounting surface 211. That is, in a state where the first substrate S1 is supported by the substrate support 210, a part of the first substrate S1 is mounted on the surface of the suppressor 300.

The substrate processing apparatus 200 further includes an elevator 310 serving as a position controller capable of controlling a positional relationship between the shower head 230 and the suppressor 300.

As illustrated in FIG. 1, the elevator 310 controls a distance between the suppressor 300 and the shower head 230 to be a first distance when the first substrate S1 is processed. In addition, the elevator 310 is configured to control the distance between the suppressor 300 and the shower head 230 to be shorter than the first distance when the second substrate S2 is processed. Specifically, the elevator 310 is controlled by the controller 280. The controller 280 sets the distance between the suppressor 300 and the shower head 230 to the first distance when the substrate S is the first substrate S1, and sets the distance between the suppressor 300 and the shower head 230 to a second distance shorter than the first distance when the substrate S is the second substrate S2. Note that the second distance may be zero, and may be a distance at which a slight gap is formed between the suppressor 300 and the shower head 230.

A plurality of recesses 302 engageable with distal ends of support pins 320 described later are formed on a back surface (lower surface) of the first portion 300a. The plurality of recesses 302 are formed at intervals in a circumferential direction of the suppressor 300.

The suppressor 300 has an insulating property. Specifically, the suppressor 300 is made of an insulating material. Examples of the insulating material include a silicon-based material such as SiO and ceramics.

The substrate processing apparatus 200 further includes the support pin 320 capable of supporting the suppressor 300. The distal ends of the support pins 320 are engaged with the recesses 302 of the suppressor 300. A plurality of the support pins 320 are provided at positions corresponding to the recesses 302 of the suppressor 300 on a bottom of the lower processing container 202b.

The plurality of support pins 320 penetrate through-holes 221 formed in the substrate support 210. The plurality of support pins 320 are attached to a support plate 322. A through-hole is formed at a center of the support plate 322. The bellows 219 passes through the through-hole.

Note that the elevator 310 controls a distance between the suppressor 300 and the shower head 230 via the support pins 320 attached to the support plate 322.

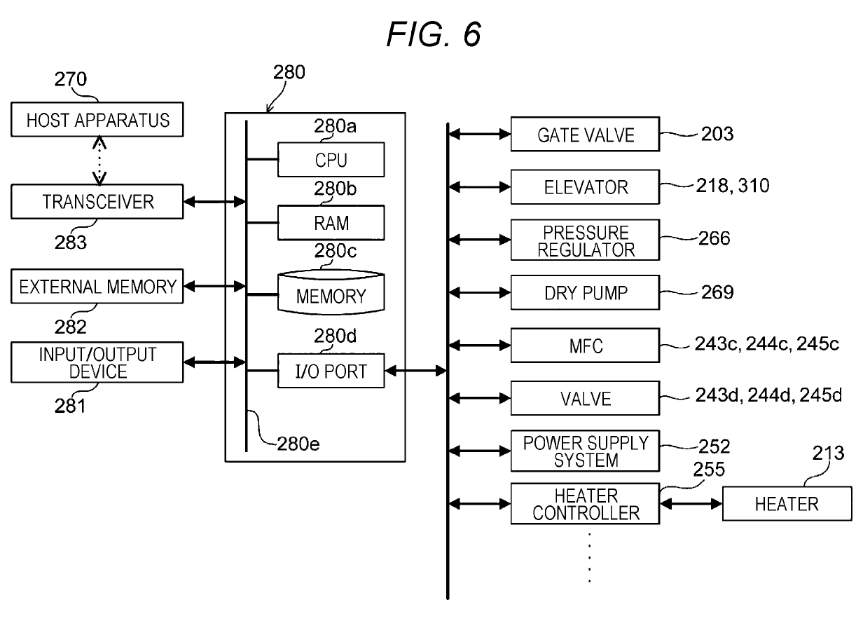

The substrate processing apparatus 200 includes the controller 280 that controls an operation of each constituent of the substrate processing apparatus 200. As illustrated in FIG. 6, the controller 280 is configured as a computer including at least a central processing unit (CPU) 280a, a random access memory (RAM) 280b, a memory 280c, and an I/O port 280d.

The RAM 280b, the memory 280c, and the I/O port 280d are configured to be able to exchange data with the CPU 280a via an internal bus 280e. An input/output device 281 configured as, for example, a touch panel is connected to the controller 280.

The memory 280c includes, for example, a flash memory, a hard disk drive (HDD), and a solid state drive (SSD). A control program for controlling an operation of the substrate processing apparatus, a process recipe in which procedures, conditions, and the like of substrate processing described later are described, and the like are readably stored in the memory 280c. The process recipe is combined to allow the controller 280 to execute each procedure in the substrate processing described later to obtain a predetermined result, and functions as a program. Hereinafter, the process recipe, the control program, and the like are collectively and simply referred to as a program. The process recipe is simply referred to as a recipe. In a case where the term “program” is used in the present specification, this may include a recipe alone, a control program alone, or both of them. The RAM 280b is configured as a memory area (work area) in which programs, data, and the like read by the CPU 280a are temporarily stored.

The I/O port 280d is connected to the gate valve 203, the MFCs 243c, 244c, and 245c, the valves 243d, 244d, and 245d, the APC valve 266, the dry pump 269, the heater 213, the elevator 218, the elevator 310, and the like.

The CPU 280a is configured to be able to read the control program from the memory 280c and execute the control program, and to read the recipe from the memory 280c in response to an input and the like of an operation command from the input/output device 281. The CPU280a is configured to be able to control flow rate regulating operations of various gases by the MFCs 243c, 244c, and 245c, opening/closing operations of the valves 243d, 244d, and 245d, an opening/closing operation of the APC valve 266, start and stop of the dry pump 269, a temperature regulating operation of the heater 213, a raising/lowering operation of the substrate support 210 by the elevator 218, a raising/lowering operation of the suppressor 300 by the elevator 310, and the like according to the content of the read recipe.

The controller 280 can be configured by installing the above-described program stored in the external memory 282 in a computer. Examples of the external memory 282 include a magnetic disk such as an HDD, an optical disk such as a CD, a magneto-optical disk such as an MO, and a semiconductor memory such as a USB memory or an SSD. The memory 280c and the external memory 282 are configured as computer-readable recording media. Hereinafter, these are also collectively and simply referred to as a recording medium. In a case where the term “recording medium” is used in the present specification, this may include the memory 280c alone, the external memory 282 alone, or both of them. Note that the program may be provided to the computer using a communicator such as the Internet or a dedicated line without using the external memory 282.

### (2) Substrate processing step

Next, a substrate processing step according to an embodiment of the present disclosure will be described. The substrate processing step according to the present embodiment is performed by the above-described substrate processing apparatus 200 as, for example, one step of a process of manufacturing a semiconductor device such as a flash memory. In the following description, the controller 280 controls an operation of each constituent of the substrate processing apparatus 200. Note that, in the following description, the processing of the substrate S will be described as a representative because the processing of the substrate S and the processing of the first substrate S1 are the same.

### Substrate loading step

First, the elevator 218 lowers the substrate support 210 to a transfer position of the substrate S to cause the lift pins 206 to pass through the through-holes 214 of the substrate support 210. Subsequently, the gate valve 203 is opened, and the substrate S is loaded into the process chamber 205 from the transfer chamber adjacent to the process chamber 205 using the transfer mechanism. The loaded substrate S is supported in a horizontal posture on the lift pins 206 protruding from the substrate mounting surface 211 of the substrate support 210. Then, the elevator 218 raises the substrate support 210, whereby the substrate S is supported by the substrate mounting surface 211 of the substrate support 210.

When the substrate S to be processed is the second substrate S2, as illustrated in FIG. 2, the elevator 310 is operated to move the suppressor 300 upward, whereby the through-holes 234a in the first region R1 of the dispersion plate 234 are closed.

### Temperature elevation/vacuum exhaust step

Subsequently, the temperature of the substrate S loaded into the process chamber 205 is elevated. Here, by energizing the heater 213, the temperature of the substrate S held on the substrate support 210 is elevated by heat of the heater 213. While the temperature of the substrate S is elevated, the inside of the process chamber 205 is vacuum-exhausted by the dry pump 269 via the exhaust pipe 262 to set a pressure in the process chamber 205 to a predetermined value. The dry pump 269 is operated until at least a substrate unloading step described later is ended.

### Process gas supply step

Next, supply of a process gas is started. Specifically, the valve 243d and the valve 244d are opened, and supply of a first gas and a second gas into the process chamber 205 is started while a flow rate is controlled by the MFC 243c and the MFC 244c.

In addition, an opening degree of the APC valve 266 is regulated such that a pressure in the process chamber 205 is a predetermined pressure to control exhaust in the process chamber 205. As described above, while the inside of the process chamber 205 is appropriately exhausted, the supply of the first gas and the second gas is continued until an end of a plasma processing step described later.

### Plasma processing step

When the pressure in the process chamber 205 is stabilized, the power supply system 252 starts supplying a high frequency into the process chamber 205. Specifically, the high-frequency power source 252b is operated to supply power. A part of the process gas in the process chamber 205 is ionized into a plasma state.

A surface layer of the substrate S mounted on the substrate mounting surface 211 of the substrate support 210 is modified by plasma.

Thereafter, when a predetermined processing time elapses, power output from the high-frequency power source 252b is stopped, and plasma discharge in the process chamber 205 is stopped. The valves 243d and 244d are closed, and the supply of the first gas and the second gas into the process chamber 205 is stopped. Thus, the plasma processing step is ended.

### Vacuum exhaust step

When the supply of the first gas and the second gas is stopped, the inside of the process chamber 205 is vacuum-exhausted via the exhaust pipe 262. As a result, the first gas and the second gas in the process chamber 205, an exhaust gas generated by a reaction of these gases, and the like are discharged to the outside of the process chamber 205. Thereafter, the opening degree of the APC valve 266 is regulated, and the pressure in the process chamber 205 is regulated to the same pressure as that of the transfer chamber adjacent to the process chamber 205. Note that the transfer chamber is a destination to which the substrate S is unloaded.

### Substrate unloading step

When the inside of the process chamber 205 reaches a predetermined pressure, the substrate support 210 is lowered to a transfer position of the substrate S, and the substrate S is supported on the lift pins 206. Then, the gate valve 203 is opened, and the substrate S is unloaded out of the process chamber 205 using the transfer mechanism.

When the processed substrate S is the second substrate S2, the elevator 310 is operated to move the suppressor 300 downward, and the suppressor 300 is housed in the counterbore 220 of the substrate support 210. Thereafter, the substrate support 210 is lowered to a transfer position of the substrate S, the second substrate S2 is supported on the lift pins 206, the gate valve 203 is opened, and the second substrate S2 is unloaded out of the process chamber 205 using the transfer mechanism.

Thus, the substrate processing step according to the present embodiment is ended.

According to the present embodiment, one or more of the following effects are obtained.

In the present embodiment, when the first substrate S1 is processed, gas is supplied into the process chamber 205 from the first region R1 and the second region R2 of the shower head 230. In the present embodiment, when the second substrate S2 having an outer diameter smaller than that of the first substrate S1 is processed, supply of gas from the first region R1 of the shower head 230 into the process chamber 205 is suppressed by the suppressor 300, and gas is supplied from the second region R2 to the process chamber 205. As a result, in the present embodiment, the amount of gas adhering to a surface of the substrate support 210 facing the first region R1 can be reduced. Specifically, it is possible to reduce the amount of gas adhering to a surface on which the second substrate S2 is not mounted outside the second substrate S2 in the substrate support 210. In other words, it is possible to reduce the amount of gas adhering to a surface facing an edge of the dispersion plate 234 in the substrate support 210. In addition, when the second substrate S2 is processed, supply of gas from the first region R1 of the shower head 230 not facing the second substrate S2 is suppressed by the suppressor, and therefore gas use efficiency can be enhanced.

In the present embodiment, since the shape of the second portion 300b of the suppressor 300 is the same as the outer shape of the second substrate S2, supply of gas to the edge E2 of the second substrate S2 can be made closer to uniform supply when the second substrate S2 is processed.

In the present embodiment, since the power supply system 252 is connected to the shower head 230, the shower head 230 functions as an electrode, and plasma is generated in the process chamber 205 to which gas is supplied by power supplied to the shower head 230. Then, the generated plasma is attracted to the substrate support 210 by the bias electrode 215. Here, in the present embodiment, since supply of gas from the first region R1 of the shower head 230 into the process chamber 205 is suppressed by the suppressor 300, it is possible to suppress generation of plasma between the first region R1 and the substrate support 210 in the process chamber 205. Furthermore, in the present embodiment, since supply of gas from the first region R1 of the shower head 230 into the process chamber 205 is suppressed by the suppressor 300, it is possible to suppress generation of plasma between the first region R1 and a portion of the bias electrode 215 facing the first region R1 in the process chamber 205.

In the present embodiment, since the suppressor 300 has an insulating property, even if the suppressor 300 comes into electrical contact with the shower head 230 to which the power supply system 252 is connected, unexpected discharge between the first region R1 of the shower head 230 and the bias electrode 215 can be suppressed.

In the present embodiment, a distance between the suppressor 300 and the shower head 230 is controlled by the elevator 310. Here, in the present embodiment, when the second substrate S2 is processed, since the distance between the suppressor 300 and the shower head 230 is shorter than the first distance, supply of gas from the first region R1 of the shower head 230 into the process chamber 205 is suppressed by the suppressor 300, and the amount of gas adhering to a surface on which the second substrate S2 is not mounted in the substrate support 210 can be further reduced.

In the present embodiment, since the suppressor 300 is supported by the support pin 320, the suppressor 300 does not affect a flow of gas in the process chamber 205 as compared with, for example, a case where the suppressor 300 is supported by a columnar support member having a larger volume than the support pin. Therefore, in the present embodiment, it is possible to suppress non-uniformity in processing of the second substrate S2.

In the present embodiment, by forming the recess 302 engageable with the support pin 320 in the first portion 300a of the suppressor 300, the suppressor 300 can be held at a fixed position with good reproducibility.

In the present embodiment, since the suppressor 300 is housed in the counterbore 220 during processing of the first substrate S1, the suppressor 300 does not affect a flow of gas in the process chamber 205 as compared with, for example, a case where the suppressor 300 protrudes from the substrate support 210. For this reason, in the substrate processing apparatus, it is possible to suppress non-uniformity in processing of the first substrate S1.

As described above, according to the technique of the present embodiment, the substrate can be stably processed regardless of the size of the substrate.

### Another embodiment

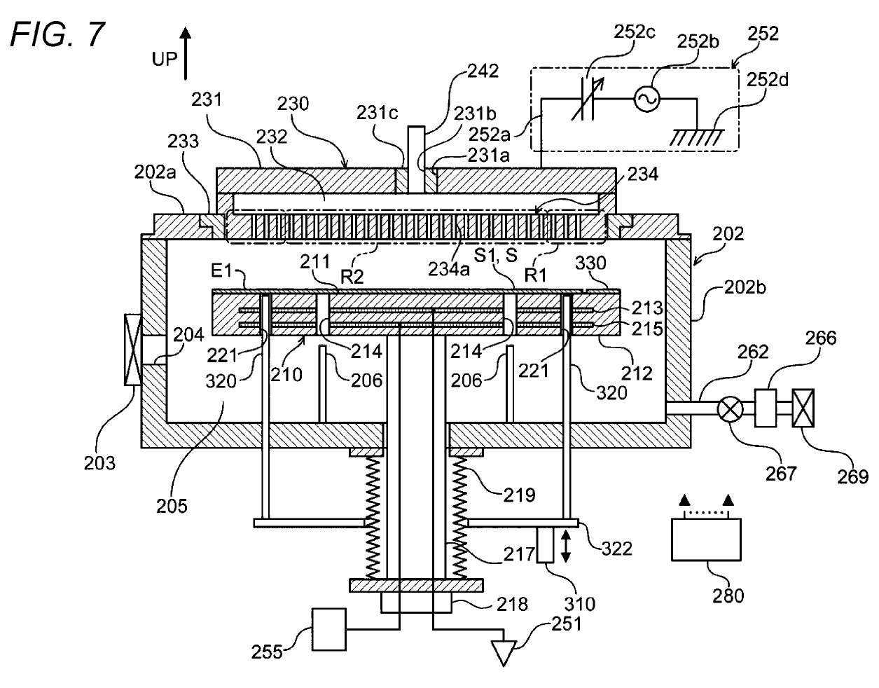

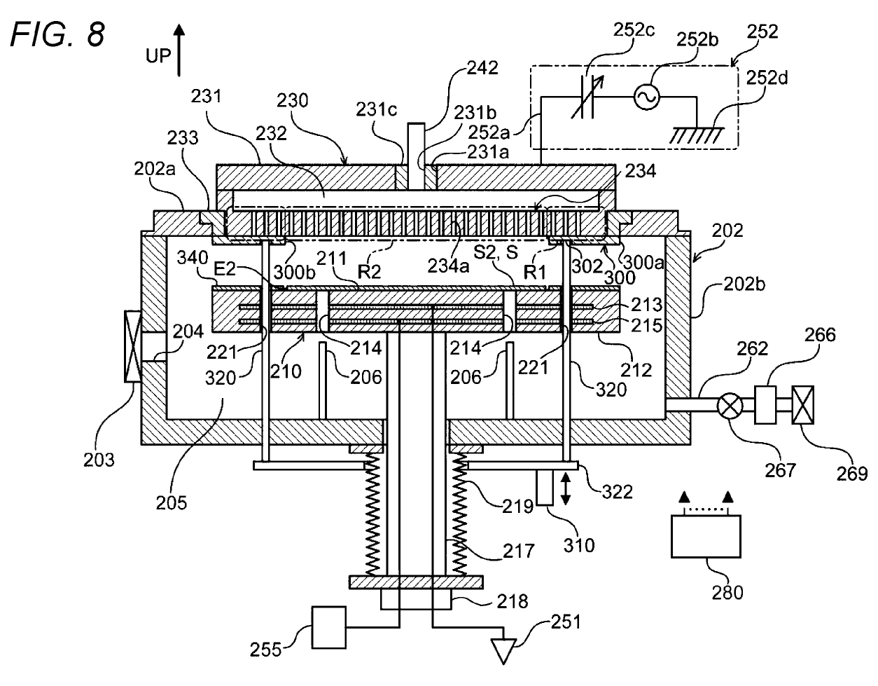

The above-described embodiment has a configuration in which the counterbore 220 is provided in the substrate support 210, and the suppressor 300 is housed in the counterbore 220, but the present disclosure is not limited to this configuration. For example, as illustrated in FIGS. 7 and 8, a first ring cover 330 or a second ring cover 340 may be disposed on the substrate mounting surface 211 without providing the counterbore 220 in the substrate support 210. Specifically, the first ring cover 330 is disposed on the substrate mounting surface 211 during processing of the first substrate S1, and the second ring cover 340 is disposed on the substrate mounting surface 211 during processing of the second substrate S2. Here, the first substrate S1 is disposed on an inner peripheral side of the first ring cover 330 in a state where the substrate support 210 supports the first substrate S1. In other words, the first ring cover 330 is disposed on an outer peripheral side of the first substrate S1 supported by the substrate support 210. In addition, the second substrate S2 is disposed on an inner peripheral side of the second ring cover 340 in a state where the substrate support 210 supports the second substrate S2. In other words, the second ring cover 340 is disposed on an outer peripheral side of the second substrate S2 supported by the substrate support 210. As described above, during processing of the first substrate S1, since the first substrate S1 is disposed on the inner peripheral side of the first ring cover 330 in a state where the substrate support 210 supports the first substrate S1, the amount of gas adhering to a surface on which the first substrate S1 is not mounted in the substrate support 210 can be reduced. In addition, during processing of the first substrate S1, since the second substrate S2 is disposed on the inner peripheral side of the second ring cover 340 in a state where the substrate support 210 supports the second substrate S2, the amount of gas adhering to a surface on which the second substrate S2 is not mounted in the substrate support 210 can be reduced. Note that when the counterbore 220 is not provided in the substrate support 210, the first substrate S1 can be mounted on the substrate mounting surface 211 by removing the suppressor 300 from the support pins 320 before the first substrate S1 is processed.

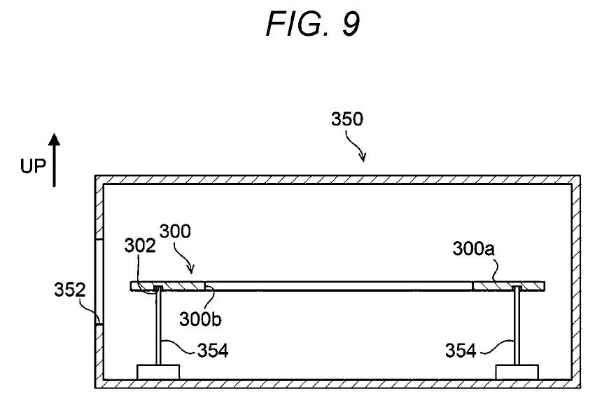

When the counterbore 220 is not provided in the substrate support 210 as in the present embodiment, a storage 350 capable of storing the suppressor 300 may be provided outside the process chamber 205. FIG. 9 illustrates the storage 350. The storage 350 includes an entrance 352 of the suppressor 300 and a support pin 354 that supports the suppressor 300. The support pin 354 is a pin having the same diameter as the support pin 320, and a distal end thereof enters the recess 302 of the suppressor 300 to support the suppressor 300. The suppressor 300 is transferred between the process chamber 205 and the storage 350 by the transfer mechanism. Note that the suppressor 300 is stored in the storage 350 when the first substrate S1 is processed, and the suppressor 300 is moved from the storage 350 onto the support pin 320 when the second substrate S2 is processed. As described above, since the suppressor 300 is stored in the storage 350 outside the process chamber 205 when the first substrate S1 is processed, the suppressor 300 is not exposed to gas in the processing of the first substrate S1. Therefore, a frequency of maintenance of the suppressor 300 can be reduced.

In the above-described embodiment, the example in which a substrate surface is processed using plasma has been described. This processing may be oxidizing or nitriding. The present disclosure is not limited to the nitriding and the oxidizing, and may be applied to any technique for performing processing on a substrate using plasma. For example, the present disclosure may be applied to modification or doping for a film formed on a substrate surface, oxide film reduction, etching for the film, resist ashing, and the like which are performed using plasma.

One embodiment of the present disclosure has been specifically described above. However, the present disclosure is not limited to the embodiments described above, and thus can be variously modified without departing from the gist of the present disclosure.

According to the present disclosure, a substrate can be stably processed regardless of the size of the substrate.

What is claimed is:

1. A substrate processing apparatus comprising:
a process chamber in which a substrate is processed;
a substrate support provided in the process chamber and capable of supporting a first substrate, or a second substrate having an outer diameter smaller than that of the first substrate;
a gas supplier including an annular first region provided at a position facing the substrate support, and having an inner diameter larger than the outer diameter of the second substrate, and a second region provided on an inner peripheral side of the first region, and capable of supplying gas into the process chamber from the first region and the second region; and
a suppressor configured to suppress supply of gas from the first region into the process chamber when the second substrate is processed.

2. The substrate processing apparatus according to claim 1, wherein:
the first region is a region facing a surface of the first substrate in a state where the first substrate is supported by the substrate support, and not facing a surface of the second substrate in a state where the second substrate is supported by the substrate support, and
the second region is a region facing a surface of the first substrate in a state where the first substrate is supported by the substrate support, and facing a surface of the second substrate in a state where the second substrate is supported by the substrate support.

3. The substrate processing apparatus according to claim 1 , wherein:
the gas supplier includes a dispersion plate having a plurality of passing portions through which gas can pass, and facing the substrate support,
the first region is formed by an edge side portion of the dispersion plate, and
the second region is constituted by a portion on an inner peripheral side of the edge side of the dispersion plate.

4. The substrate processing apparatus according to claim 1, wherein:
the suppressor is provided at a position facing the substrate support, and includes a first portion that suppresses supply of gas from the first region into the process chamber, and a second portion serving as a hole through which gas can pass, and
a diameter of the second portion is configured to be larger than an outer diameter of the second substrate and smaller than an outer diameter of the first substrate.

5. The substrate processing apparatus according to claim 4, wherein:
the first region is a region facing an edge of the first substrate in a state where the first substrate is supported by the substrate support, and not facing the second substrate in a state where the second substrate is supported by the substrate support,
the second region is a region facing a central portion of the first substrate in a state where the first substrate is supported by the substrate support, and facing the second substrate in a state where the second substrate is supported by the substrate support, and
the first portion is disposed at least below the first region when the second substrate is processed.

6. The substrate processing apparatus according to claim 4, wherein:
the gas supplier includes a dispersion plate having a plurality of passing portions through which gas can pass, and facing the substrate support,
the first region is formed by an edge side portion of the dispersion plate,
the second region is constituted by a portion on an inner peripheral side of the edge side, and
the first portion is disposed at least below the first region when the second substrate is processed.

7. The substrate processing apparatus according to claim 1, wherein:
the suppressor is provided at a position facing the substrate support, and includes a first portion that suppresses supply of gas from the first region into the process chamber, and a second portion serving as a hole through which gas can pass, and
a shape of the second portion is the same as an outer shape of the second substrate.

8. The substrate processing apparatus according to claim 1, wherein:
the suppressor is provided at a position facing the substrate support, and includes a first portion that suppresses supply of gas from the first region into the process chamber, and a second portion serving as a hole through which gas can pass, and
the first portion is disposed above a surface that does not support the second substrate in the substrate support in a state where the second substrate is supported by the substrate support.

9. The substrate processing apparatus according to claim 1, wherein:
a power supply system is connected to the gas supplier,
an electrode is provided in the substrate support, and
the suppressor is disposed between the electrode and the gas supplier when the second substrate is processed.

10. The substrate processing apparatus according to claim 9, wherein:
the suppressor is disposed between a portion facing the first region in the electrode and the first region.

11. The substrate processing apparatus according to claim 9, wherein:
the suppressor has an insulating property.

12. The substrate processing apparatus according to claim 1, further comprising a position controller capable of controlling a positional relationship between the gas supplier and the suppressor, wherein:
the position controller is configured to:
control a distance between the suppressor and the gas supplier to be a first distance when the first substrate is processed, and
control the distance between the suppressor and the gas supplier to be shorter than the first distance when the second substrate is processed.

13. The substrate processing apparatus according to claim 12, further comprising a support pin capable of supporting the suppressor, wherein:
the position controller controls a distance between the suppressor and the gas supplier via the support pin.

14. The substrate processing apparatus according to claim 13, wherein:
the suppressor is provided at a position facing the substrate support, and includes a first portion that suppresses supply of gas from the first region into the process chamber, and a second portion serving as a hole through which gas can pass, and
a recess engageable with the support pin is formed in the first portion.

15. The substrate processing apparatus according to claim 1, wherein:
a counterbore capable of housing the suppressor is provided in the substrate support, and
the suppressor is housed in the counterbore when the first substrate is processed.

16. The substrate processing apparatus according to claim 1, wherein:
a storage capable of storing the suppressor is provided outside the process chamber,
the suppressor is stored in the storage when the first substrate is processed, and
the suppressor is moved from the storage onto the support pin when the second substrate is processed.

17. The substrate processing apparatus according to claim 1, wherein a first ring cover on an inner peripheral side of which the first substrate is disposed in a state where the first substrate is supported or a second ring cover on an inner peripheral side of which the second substrate is disposed in a state where the second substrate is supported and whose inner diameter is smaller than an inner diameter of the first ring cover is disposed in the substrate support.

18. A method of processing a substrate, comprising:
causing a substrate support provided in a process chamber in which a substrate is processed and capable of supporting a first substrate or a second substrate having an outer diameter smaller than that of the first substrate to support the second substrate; and
causing a gas supplier including an annular first region having an inner diameter larger than the outer diameter of the second substrate, and a second region provided on an inner peripheral side of the first region, and capable of supplying gas into the process chamber from the first region and the second region to process the second substrate by supplying gas into the process chamber in a state where a suppressor suppresses supply of gas from the first region into the process chamber.

19. A method of manufacturing a semiconductor device, comprising the method of processing a substrate according to claim 18.

20. A non-transitory computer-readable recording medium storing a program that causes, by a computer, a substrate processing apparatus to execute a method of processing a substrate, comprising:
causing a substrate support provided in a process chamber in which a substrate is processed and capable of supporting a first substrate or a second substrate having an outer diameter smaller than that of the first substrate to support the second substrate; and
causing a gas supplier including an annular first region having an inner diameter larger than the outer diameter of the second substrate, and a second region provided on an inner peripheral side of the first region, and capable of supplying gas into the process chamber from the first region and the second region to process the second substrate by supplying gas into the process chamber in a state where a suppressor suppresses supply of gas from the first region into the process chamber.
